(19) United States
(12) Patent Application Publication
(10) Pub. No.: US 2025/0357139 A1
(43) Pub. Date: Nov. 20, 2025

(54) PLANARIZATION APPARATUS, PLANARIZATION METHOD, AND ARTICLE MANUFACTURING METHOD

(71) Applicant: CANON KABUSHIKI KAISHA, Tokyo (JP)

(72) Inventors: RYO NAWATA, Tochigi (JP); YOICHI MATSUOKA, Tochigi (JP); YOSUKE MURAKAMI, Tochigi (JP)

(21) Appl. No.: 19/196,647

(22) Filed: May 1, 2025

(30) Foreign Application Priority Data
May 14, 2024 (JP) 2024-078778

(51) Int. Cl. H01L 21/321; H01L 21/66; H01L 21/67; H01L 21/68; H01L 23/544

(52) U.S. Cl. CPC H01L 21/32115; H01L 21/67132; H01L 21/68; H01L 22/12; H01L 23/544

(57) ABSTRACT

A planarization apparatus configured to form a planarization layer on a substrate by bringing a planarization member into contact with a planarization material on the substrate includes a drive unit configured to move the planarization member and the substrate relative to each other, and a control unit configured to control the drive unit. The control unit controls a position of the planarization member relative to the substrate based on information about a defect on the planarization member and information about a tolerance region of the substrate where a defect is tolerated.

### BACKGROUND OF THE DISCLOSURE

### Field of the Disclosure

The present disclosure relates to a planarization apparatus, a planarization method, and an article manufacturing method.

### Description of the Related Art

A technique (planarization technique) for planarizing unevenness on a substrate by forming a coating film on a substrate using a coating apparatus, such as a spin coater, is known. However, this planarization technique using the coating apparatus is inadequate for planarizing nanoscale unevenness on a substrate. Thus, in recent years, planarizing a substrate using imprinting technology is discussed.

Japanese Unexamined Patent Application Publication (Translation of PCT Application) No. 2011-529626 discusses improving planarization accuracy by dripping a planarization material based on unevenness on a substrate and curing the planarization material while a planarization member is in contact with the dripped planarization material. Planarization using imprinting technology may include a process in which the planarization material on the substrate is cured by irradiating it with light while the planarization member as a pressing member is in contact with the planarization material. Thus, a material that transmits light, such as quartz glass, is used in the planarization member. Since the goal is planarization, the surface of the planarization member that is brought into contact with the planarization material on the substrate is a flat surface.

Japanese Patent Application Laid-Open No. 2019-145620 discusses how defects occur on a planarization member due to the attachment of a planarization material on a substrate to the planarization member and how the defects (contaminants) on the planarization member grow with repeated planarization processes. In Japanese Patent Application Laid-Open No. 2019-145620, the relative positional relationship between the planarization member and the substrate is changed each time the planarization process is performed a predetermined number of times to prevent the defects on the planarization member from growing.

However, since a planarization apparatus discussed in Japanese Patent Application Laid-Open No. 2019-145620 changes the relative positional relationship between the planarization member and the substrate each time the planarization process is performed the predetermined number of times, the defects on the planarization member may be transferred to a position on the substrate, which may cause a defective chip.

### SUMMARY OF THE DISCLOSURE

According to an aspect of the present disclosure, a planarization apparatus configured to form a planarization layer on a substrate by bringing a planarization member into contact with a planarization material on the substrate includes a drive unit configured to move the planarization member and the substrate relative to each other, and a control unit configured to control the drive unit. The control unit controls a position of the planarization member relative to the substrate based on information about a defect on the planarization member and information about a tolerance region of the substrate where a defect is tolerated.

Further features of the present disclosure will become apparent from the following description of exemplary embodiments with reference to the attached drawings.

### BRIEF DESCRIPTION OF THE DRAWINGS

FIG. 1 is a diagram illustrating a planarization apparatus according to a first exemplary embodiment.

FIGS. 2A and 2B are diagrams illustrating a planarization member.

FIGS. 3A and 3B are diagrams illustrating measurements performed by a pre-alignment unit.

FIGS. 4A to 4F are diagrams illustrating a planarization process.

FIGS. 5A and 5B are diagrams illustrating how a defective chip occurs due to a defect on the planarization member.

FIGS. 6A to 6E are diagrams illustrating a method of controlling the position of the planarization member relative to a substrate.

FIG. 7 is a flowchart illustrating a method of controlling the position of the planarization member relative to the substrate.

FIG. 8 is a diagram illustrating a planarization apparatus according to a third exemplary embodiment.

### DESCRIPTION OF THE EMBODIMENTS

As described below, an exemplary embodiment of the present disclosure provides a planarization apparatus that reduces defective chips caused by defects on a planarization member.

Various exemplary embodiments of the present disclosure will be described below with reference to the attached drawings. It should be noted that corresponding components are assigned the same reference numerals, and redundant descriptions are omitted.

In the drawings of the exemplary embodiments, directions are indicated in an XYZ coordinate system where the XY plane is defined as a direction parallel to a surface of a substrate. The directions parallel to the X-, Y-, and Z-axes in the XYZ coordinate system are defined as X-, Y-, and Z-directions, respectively, and the rotations around the X-, Y-, and Z-axes are denoted as OX, OY, and OZ, respectively. Control or drive with respect to the X-, Y-, and Z-axes refers to control or drive in the directions parallel to the X-, Y-, and Z-directions, respectively.

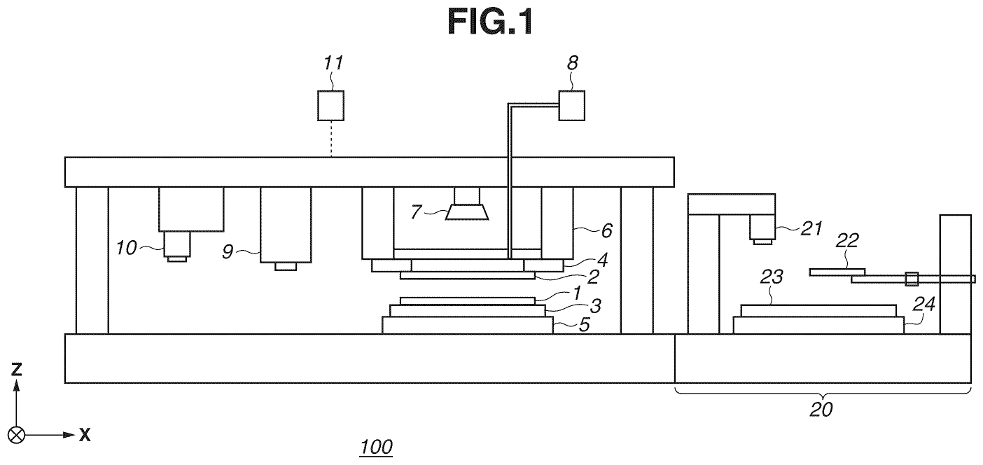

FIG. 1 is an outline diagram illustrating a planarization apparatus 100 according to a first exemplary embodiment. The planarization apparatus 100 can be used in manufacturing an article, such as a semiconductor device, and is used to form a planarization layer to planarize a surface of a substrate to prevent defects on the article. A planarization process performed by the planarization apparatus 100 may include at least the following steps.
(a) A supply step of supplying a curable composition, such as a planarization material, to a substrate.
(b) A contact step of bringing the planarization material supplied to the substrate into contact with a planarization member.
(c) A curing step of curing the planarization material by applying energy for curing.
(d) A separation step of separating the planarization member from the cured planarization material (planarization layer) on the substrate.

Through the planarization process, the unevenness on the substrate is covered with the planarization layer, and a surface layer of the planarization layer is pressed by the planarization member to obtain a flat surface. A curable composition that cures upon receiving energy for curing is used as the planarization material. For example, heat or light, such as ultraviolet light, can be used as the energy for curing. Hereinafter, irradiating the planarization material with light that induces a curing reaction is referred to as exposure.

In the present exemplary embodiment, the description is provided using a photocurable composition that cures upon light irradiation as the planarization material. The photocurable composition contains at least a plurality of polymerizable compounds and a photopolymerization initiator that generates a polymerization factor in response to a specific wavelength.

The planarization apparatus 100 illustrated in FIG. 1 includes a substrate 1, a substrate holding unit 3, a substrate drive unit 5, a planarization member 2, a planarization member holding unit 4, a planarization member drive unit 6, a curing unit 7, a pressure adjustment unit 8, a supply unit 9, an alignment unit 10, and a control unit 11.

A substrate used in device manufacturing, such as a semiconductor wafer on which a pattern is formed, a micro-electro-mechanical system (MEMS) wafer, a power semiconductor wafer, a glass substrate for displays, or a biological element, can be used as the substrate 1, and the substrate 1 may include a plurality of layers on a base material. For example, a semiconductor, glass, ceramics, a metal, or a resin can be used as the base material. As necessary, a bonding layer may be provided to the substrate 1 to improve adhesion between the planarization material and the substrate 1.

The substrate 1 preferably includes a mark (reference mark) that can serve as a reference for measuring the rotation OZ of the substrate 1 around the Z-axis. A possible reference mark could be a mark formed on the substrate 1 during pre-processing or a notch pre-formed on the substrate 1.

The planarization member 2 is a member that is also referred to as a “super straight” member and is preferably made of a material that allows ultraviolet light to pass through, such as quartz, and has an outer shape equal to or larger than that of the substrate 1. Preferred materials for the planarization member 2 include, specifically, glass, quartz, polymethyl methacrylate (PMMA), light-transmissive resins such as polycarbonate resin, transparent metal vapor-deposited films, flexible films such as polydimethylsiloxane, photocurable films, and metal films. It should be noted that the planarization member 2 preferably has a circular shape with a diameter greater than 300 mm and less than 500 mm, but this is not a limitation. Preferably, the diameter of the planarization member 2 may be 200 mm to 400 mm. Further, the planarization member 2 preferably has a thickness of 0.25 mm or more and less than 2 mm, but this is not a limitation.

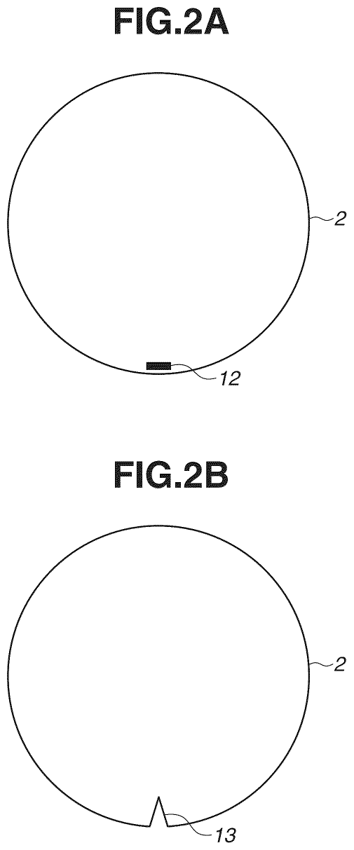

The planarization member 2 preferably includes a mark (reference mark) that can serve as a reference for measuring the rotation OZ of the planarization member 2 around the Z-axis. A possible reference mark could be a T7 mark 12 of the Semiconductor Equipment and Materials International (SEMI) standard illustrated in FIG. 2A or a notch 13 illustrated in FIG. 2B.

The substrate holding unit 3 is configured to hold the substrate 1, and the substrate 1 conveyed by a conveyance hand 15 is held by the substrate holding unit 3 using vacuum suction or electrostatic force.

The planarization member holding unit 4 is configured to hold the planarization member 2, and the planarization member 2 conveyed by the conveyance hand 15 is held by the planarization member holding unit 4 using vacuum suction or electrostatic force.

The substrate drive unit 5 is configured to move the substrate holding unit 3 in the X- and Y-directions. A linear motor is used as an actuator. Further, the substrate drive unit 5 is preferably equipped with a measuring instrument, such as an encoder or a laser interferometer, for position measurement. By moving the substrate holding unit 3 with the substrate 1 placed thereon in the X- and Y-directions, the substrate 1 can be positioned directly below the planarization member 2 or the supply unit 9 in the Z-direction.

The planarization member drive unit 6 is configured to move the planarization member 2 in the Z-direction. It includes an actuator such as a linear motor or an air cylinder. The planarization member drive unit 6 controls the distance between the substrate 1 and the planarization member 2, thereby bringing the substrate 1 and the planarization member into contact with each other or separating them. Furthermore, the planarization member drive unit 6 can drive around the OX- and OY-axes and can be used to adjust the parallelism between the substrate 1 and the planarization member 2.

The curing unit 7 is configured to irradiate the planarization material with energy for curing (e.g., light such as ultraviolet light) and includes a light source configured to emit light that cures the planarization material (exposure light such as ultraviolet light). Further, the curing unit 7 may include an optical element to adjust the light emitted from the light source to make the light suitable for planarization. The light emitted from the curing unit 7 passes through the planarization member 2 and exposes the planarization material on the substrate 1.

While the substrate drive unit 5 and the planarization member drive unit 6 form a drive unit that realizes the relative movement between the substrate 1 and the planarization member in the present exemplary embodiment, this is not a limiting configuration, and a drive unit in which only either the substrate drive unit 5 or the planarization member drive unit 6 is configured to move may be employed.

The pressure adjustment unit 8 is configured to adjust the pressure in the space on the side of the planarization member 2 opposite the substrate 1 (upper surface in the Z-direction). It may include, for example, an air regulator, a pressure pump, and/or a vacuum pump. By adjusting the pressure in the space, the planarization member 2 can be curved in the Z-direction. During the pressing of the planarization member 2 against the substrate 1, the planarization member 2 is curved outward toward the substrate 1. This is to sequentially bring the planarization member 2 into contact from the center toward the outer edge to ensure that no air is trapped between the planarization member 2 and the substrate 1. After the substrate 1 and the planarization member 2 are fully brought into contact via the planarization material, the pressure is released.

The supply unit 9 is configured to supply the planarization material to the substrate 1 using an inkjet method. The supply unit 9 may include a tank for storing an inkjet chip and/or a tank for storing the planarization material. While the substrate drive unit 5 moves the substrate 1, the supply unit 9 drips the planarization material, thereby providing the planarization material with a desired distribution on the substrate 1.

The alignment unit 10 is configured to detect an alignment mark formed on the substrate 1 and includes lighting, an optical element, and a camera. The alignment mark is detected while being held by the substrate holding unit 3. This improves the accuracy of the supply position of the planarization material relative to the substrate 1.

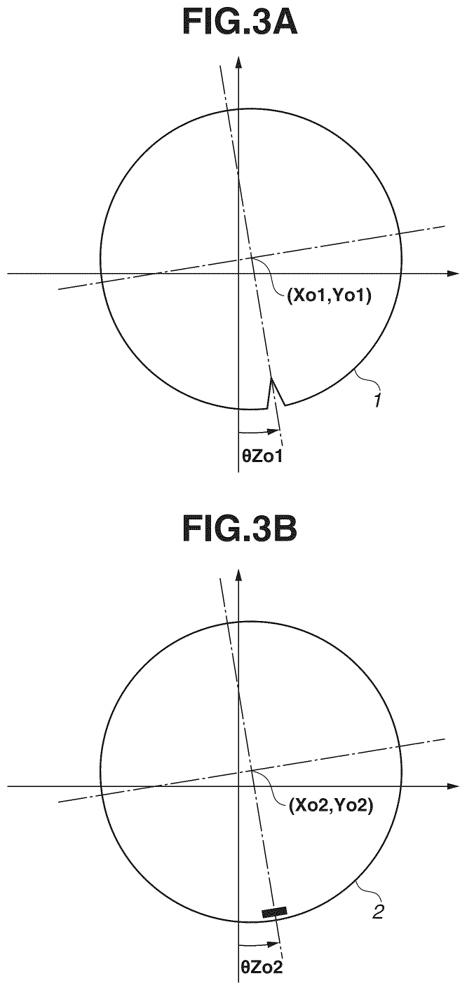

A pre-alignment unit 20 includes a camera 21 and measures the outer shape and a notch of the substrate 1 placed on a pre-alignment holding unit 23. From the measurement results of the outer shape of the substrate 1, the central coordinates (Xo1, Yo1) of the substrate 1 can be calculated, as illustrated in FIG. 3A, and from the relationship between the central coordinates and the notch of the substrate 1, the rotation θZo1 of the substrate 1 around the Z-axis illustrated in FIG. 3A can be calculated. Similarly, by measuring the outer shape and the rotation position reference mark of the planarization member 2 placed on the pre-alignment holding unit 23, the central coordinates (Xo2, Yo2) of the planarization member 2 and the rotation θZo2 around the Z-axis can be determined, as illustrated in FIG. 3B. The pre-alignment unit 20 according to the first exemplary embodiment further includes a rotation drive unit 24 and can rotate the substrate 1 and the planarization member 2 at a desired angle.

The control unit 11 is configured to control each component of the planarization apparatus 100 and includes a memory, a central processing unit (CPU), and control software.

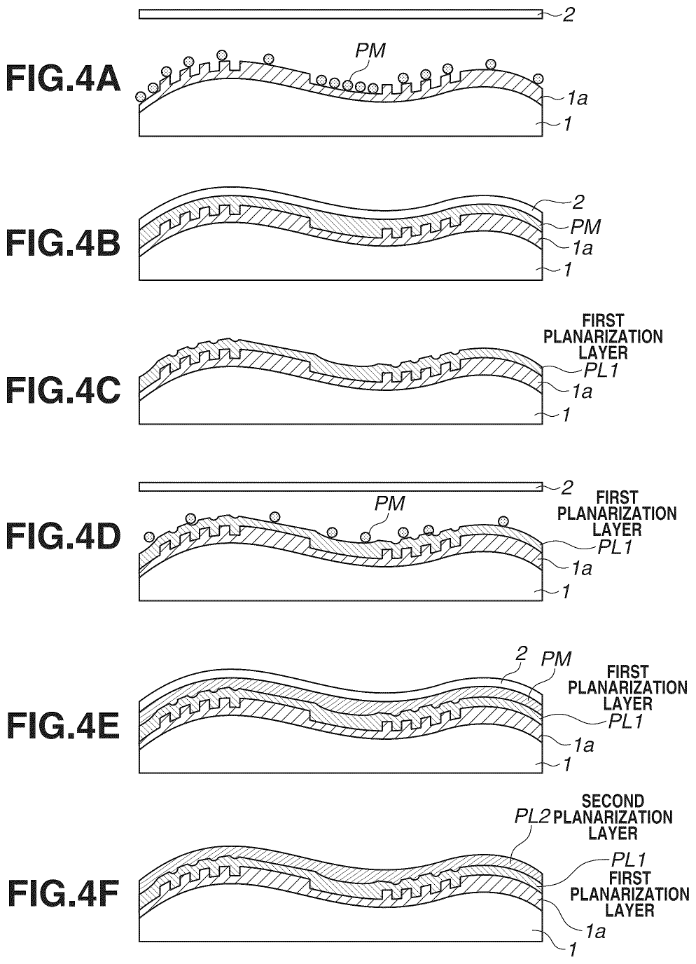

Next, a planarization process will be described with reference to FIGS. 4A to 4F. First, the supply unit 9 supplies a planarization material PM to the substrate 1 on which an underlying pattern 1a is formed (supply step). FIG. 4A illustrates a state after the planarization material PM is placed on the substrate 1 and before the planarization member 2 is brought into contact. Since the planarization material PM is supplied using the inkjet method, droplets are on the substrate 1. The density distribution of the droplets varies depending on the unevenness of the underlying pattern 1a.

Next, the planarization material PM on the substrate 1 and the planarization member 2 are brought into contact with each other. By bringing the planarization member 2 into contact with the planarization material PM, the planarization material PM spreads across the entire surface of the substrate 1. FIG. 4B illustrates a state where the entire surface of the planarization member 2 is in contact with the planarization material PM on the substrate 1 and the planarization member 2 conforms to the surface shape of the substrate 1 (contact step). In this state, the curing unit 7 exposes the planarization material PM, thereby curing the planarization material PM (curing step). Thereafter, the planarization member 2 is separated from the cured planarization material PM on the substrate 1 (separation step).

FIG. 4C illustrates the substrate 1 after the planarization member 2 is separated. A first planarization layer with improved flatness is formed across the entire surface of the substrate 1. However, there may be a case where the planarization material PM shrinks in its thickness direction due to curing shrinkage during the curing of the planarization material PM and does not become completely flat.

To form a flatter planarization layer, the supply unit 9 may additionally supply the planarization material PM onto the formed first planarization layer. FIG. 4D illustrates a state where the additional planarization material PM is supplied onto the formed planarization layer. The amount and distribution of the supplied planarization material PM differ from those used in forming the first planarization layer. It is sufficient to supply the planarization material PM in an amount necessary to flatten the unevenness of the surface of first planarization layer.

Next, the planarization member 2 is pressed against the planarization material PM. FIG. 4E illustrates a state where the planarization member 2 is pressed against the planarization material PM. In this state, the planarization material PM is exposed and cured. Thereafter, the planarization member 2 is separated from the planarization material PM.

FIG. 4F illustrates the substrate 1 in a state where the planarization member 2 is separated from the substrate 1. A second planarization layer is formed on the first planarization layer. As described above, by repeating the process of supplying the planarization material PM and pressing the planarization member 2 a plurality of times, the flatness can be improved compared to the first planarization layer alone.

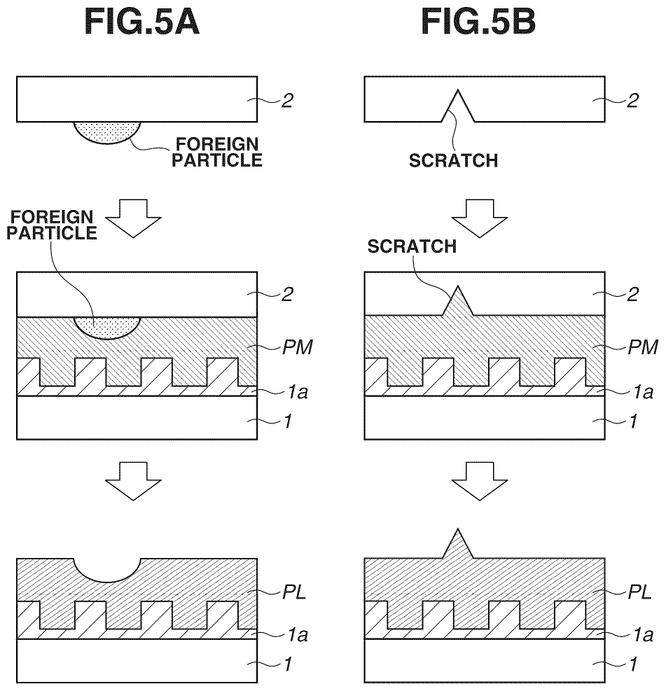

While the planarization layer can be formed on the substrate 1 as described above, for some reasons, a foreign particle or scratch may be present on the surface of the planarization member 2. In a case where a foreign particle is present on the planarization member 2, the shape of the foreign particle is transferred onto the planarization layer formed on the substrate 1, as illustrated in FIG. 5A. In a case where a scratch is present on the planarization member 2, the shape of the scratch is transferred onto the planarization layer formed on the substrate 1, as illustrated in FIG. 5B. In both cases of FIGS. 5A and 5B, the flatness of the planarization layer deteriorates. With such a planarization layer, an adverse effect, such as a deterioration in resolution, may occur in subsequent steps after the planarization, such as an exposure step in an exposure apparatus, and a defective chip may be generated.

To avoid this, it is necessary to prepare the planarization member 2 that is sufficiently flat. However, it is difficult to perfectly prevent scratches and foreign particles during the manufacturing step. Further, as the use of the planarization member 2 is increased, a new scratch may occur, or a foreign particle may adhere. Thus, the planarization apparatus 100 according to the present exemplary embodiment is directed to reducing the occurrence of defective chips caused by scratches or foreign particles on the planarization member 2, and controls the position of the planarization member 2 relative to the substrate 1 to reduce the occurrence of defective chips caused by scratches or foreign particles on the planarization member 2. Next, a method for controlling the position of the planarization member 2 relative to the substrate 1 will be described. Hereinafter, the unevenness of the surface of the planarization member 2, such as scratches or foreign particles, will be referred to as a “defect”.

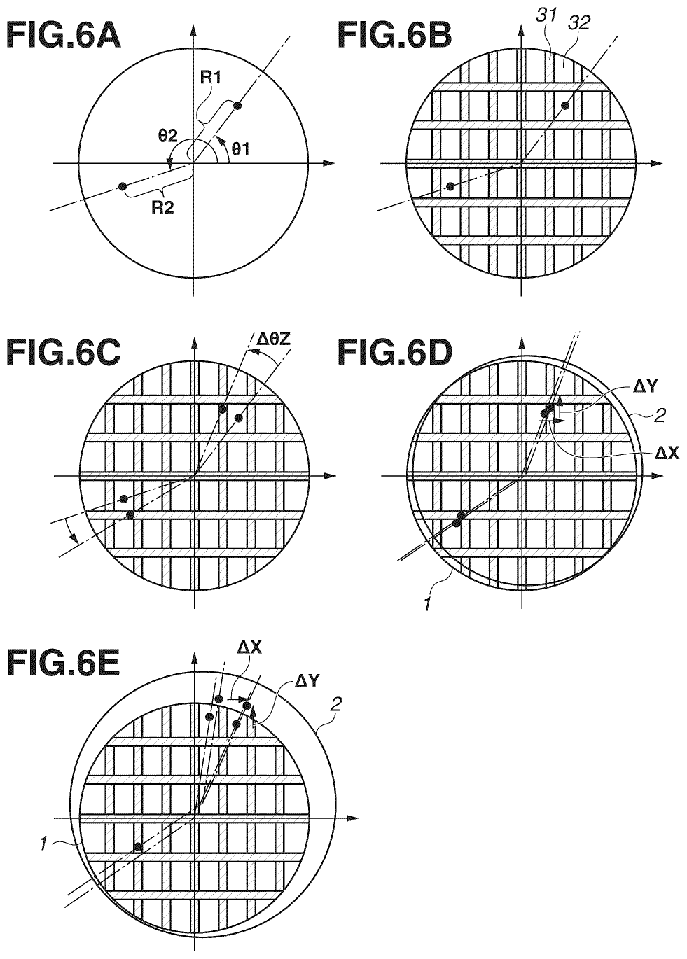

In the control unit 11 of the planarization apparatus 100, information about the defect on the planarization member 2 is stored as defect information. FIG. 6A is a schematic diagram illustrating an example of information about the defect on the planarization member 2. FIG. 6B illustrates a state where the planarization member 2 and the substrate 1 illustrated in FIG. 4B are in contact with each other via the planarization material. In FIG. 6B, scribe lines 31 each represent a scribe line that is a tolerance region of the substrate 1 where a defect is tolerated, and chip regions 32 each represent a chip region of the substrate 1. In FIG. 6B, since defects on the planarization member 2 are in the chip regions 32 of the substrate 1, the chips may become defective chips. Thus, in the first exemplary embodiment, the position of the planarization member 2 relative to the substrate 1 is controlled so that the defects on the planarization member 2 are positioned opposite the scribe lines 31 on the substrate 1, as illustrated in FIG. 6C or 6D, thereby reducing the occurrence of defective chips caused by the defects on the planarization member 2.

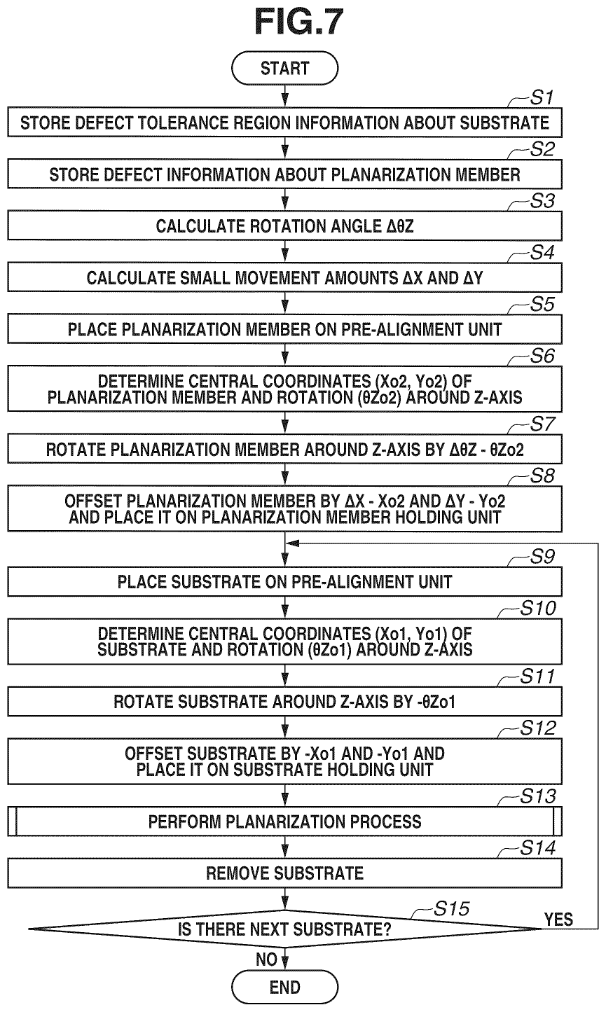

Next, the method for controlling the position of the planarization member 2 relative to the substrate 1 will be described more specifically with reference to a flowchart in FIG. 7.

In step one (S1), information about a defect tolerance region of the substrate 1 illustrated in FIG. 6B is stored in the control unit 11 of the planarization apparatus 100. The information about the defect tolerance region is stored in a form, for example, represented by formula 1 with the center of the substrate 1 as the origin. In formula 1, ¿ denotes the width of the scribe lines. The defect tolerance region of the substrate 1 includes the scribe lines of the substrate 1, portions without a pattern, portions with a thick pattern where a defect can be tolerated, and portions outside the wafer.

$$\{ \begin{matrix}A 1 - ε / 2 < X < A 1 + ε / 2 \\ A 2 - ε / 2 < X < A 2 + ε / 2 \\ ⋮ \\ A 1 - ε / 2 < X < A 1 + ε / 2\end{matrix} \qquad [ Formula 1 ]$$

$$\{ \begin{matrix}B 1 - ε / 2 < X < B 1 + ε / 2 \\ B 2 - ε / 2 < X < B 2 + ε / 2 \\ ⋮ \\ B m - ε / 2 < X < B m + ε / 2\end{matrix}$$

In step two (S2), the defect information about the planarization member 2 illustrated in FIG. 6A is stored in the control unit 11 of the planarization apparatus 100. The defect information about the planarization member 2 is stored in a form, for example, represented by formula 2 with the center of the planarization member 2 as the origin. The defect information about the planarization member 2 may be obtained based on the defect measurement results of a substrate previously planarized with the planarization member 2 to be used in this case, or may be obtained using the measurement results measured by a defect inspection apparatus capable of measuring defects on the planarization member 2.

$$\{ \begin{matrix}X = R 1 \cdot cos ( θ 1 ) \\ Y = R 1 \cdot sin ( θ 1 ) \\ X = R 2 \cdot cos ( θ 2 ) \\ Y = R 2 \cdot sin ( θ 2 ) \\ ⋮ \\ X = R n \cdot cos ( θ n ) \\ Y = R n \cdot sin ( θ n )\end{matrix} \qquad [ Formula 2 ]$$

In step three (S3), the control unit 11 calculates the rotation angle ΔθZ using formulas 1 and 2 to align as many defects on the planarization member 2 as possible with the defect tolerance region of the substrate 1, as illustrated in FIG. 6C.

In step four (S4), in a case where more defects on the planarization member 2 can be moved into the defect tolerance region of the substrate 1 by moving the planarization member 2 relative to the substrate 1 in the X-axis and Y-axis directions by small amounts as illustrated in FIG. 6D, the control unit 11 calculates the small movement amounts ΔX and ΔY. The magnitude of the small movement amounts ΔX and ΔY may be set within, for example, a wafer edge exclusion (WEE) range. In a case where the outer shape of the planarization member 2 is larger than the substrate 1 as illustrated in FIG. 6E, the magnitude of the small movement amounts ΔX and ΔY can be set to a value greater than or equal to the WEE of the substrate 1.

In step five (S5), the planarization member 2 is placed on the pre-alignment unit 20.

In step six (S6), the outer shape and a notch of the planarization member 2 are measured, and the central coordinates (Xo2, Yo2) of the planarization member 2 and the rotation (θZo2) around the Z-axis are determined, as illustrated in FIG. 3B.

In step seven (S7), a rotation mechanism unit 14 rotates the planarization member 2 around the Z-axis by ΔθZ-θZo2.

In step eight (S8), the planarization member 2 is offset by ΔX-Xo2 in the X-axis direction and ΔY-Yo2 in the Y-axis direction and placed on the planarization member holding unit 4 by the conveyance hand 15.

In step nine (S9), the substrate 1 is placed on the pre-alignment unit 20.

In step ten (S10), the outer shape and the notch of the substrate 1 are measured, and the central coordinates (Xo1, Yo1) of the substrate 1 and the rotation (θZo1) around the Z-axis are determined, as illustrated in FIG. 3A.

In step eleven (S11), the rotation mechanism unit 14 rotates the substrate 1 around the Z-axis by −θZo1.

In step twelve (S12), the substrate 1 is offset by −Xo1 in the X-axis direction and −Yo2 in the Y-axis direction and placed on the substrate holding unit 3 by the conveyance hand 15.

In step thirteen (S13), the planarization process illustrated in FIGS. 4A to 4F is performed.

In step fourteen (S14), the substrate 1 is removed from the planarization apparatus 100.

In step fifteen (S15), in a case where there is a plurality of substrates 1 to be planarized, steps nine (S9) to fourteen (S14) are repeated.

Through the above-described flow, the process of planarizing the substrate 1 can be performed to move the defects on the planarization member 2 into the defect tolerance region of the substrate 1.

As described above, the first exemplary embodiment adjusts the position of the planarization member 2 relative to the substrate 1 based on information about the defect on the planarization member 2 and information about the tolerance region of the substrate 1 where a defect is tolerated so that at least one defect on the planarization member 2 is positioned opposite the tolerance region of the substrate 1. This makes it possible to perform the planarization process on the substrate 1 to move the defect on the planarization member 2 into the defect tolerance region of the substrate 1, thereby reducing the occurrences of defective chips caused by defects on the planarization member 2. Further, in step three (S3), a calculation condition may be set so that at least the defect with the largest area on the planarization member 2 is positioned opposite the tolerance region of the substrate 1.

A second exemplary embodiment will be described. In the first exemplary embodiment, the planarization member 2 is placed on the planarization member holding unit 4 with the small movement amounts ΔX and ΔY taken into account in step eight (S8). The planarization apparatus 100 according to the first exemplary embodiment includes the substrate drive unit 5 configured to drive the substrate holding unit 3 on which the substrate 1 is placed in the X-axis and Y-axis directions.

On the other hand, in the second exemplary embodiment, the planarization member 2 is placed on the planarization member holding unit 4 without taking into account the small movement amounts ΔX and ΔY in step eight (S8), and during the planarization process in step thirteen (S13), the substrate drive unit 5 is driven to move the substrate 1 by −ΔX and −ΔY from the normal planarization position, and the planarization process is performed.

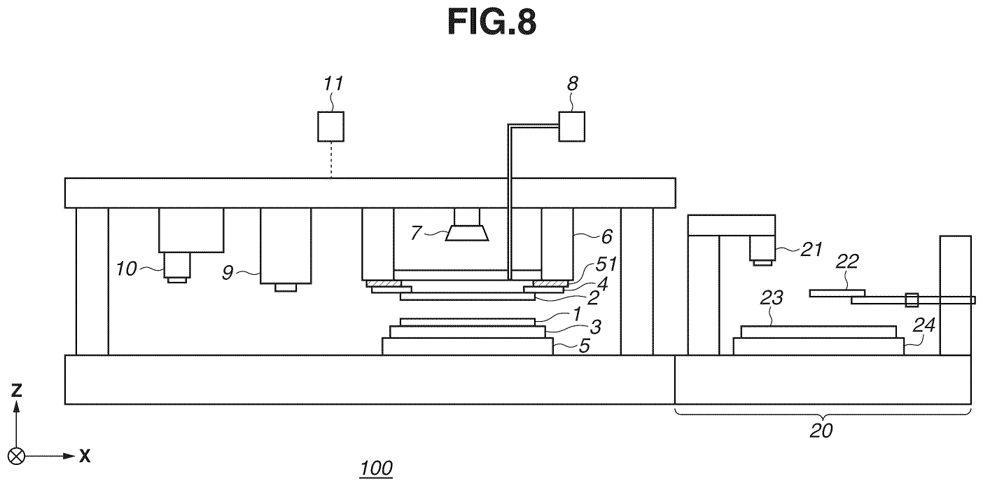

In the planarization apparatus 100 according to a third exemplary embodiment, the planarization member holding unit 4 further includes a planarization member horizontal drive unit 51 configured to drive the planarization member 2 in the X-axis and Y-axis directions and around the Z-axis, as illustrated in FIG. 8. In the first exemplary embodiment, the planarization member 2 is placed on the planarization member holding unit 4 with the rotation angle ΔθZ and the small movement amounts ΔX and ΔY taken into account in steps seven (S7) and eight (S8). In the third exemplary embodiment, the planarization member 2 is placed on the planarization member holding unit 4 without taking into account the rotation angle ΔθZ and the small movement amounts ΔX and ΔY in steps seven (S7) and eight (S8), and during the planarization process in step thirteen (S13), the planarization member horizontal drive unit 51 is driven to move the planarization member 2 by ΔθZ around the Z-axis, ΔX in the X-axis direction, and ΔY in the Y-axis direction from the normal planarization position, and the planarization process is performed.

The exemplary embodiments described above are capable of reducing the occurrences of defective chips caused by defects on the planarization member 2.

### <Exemplary Embodiment of Article Manufacturing Method>

Next, a method for manufacturing an article (such as a semiconductor integrated circuit (semiconductor IC) device, a liquid crystal display device, a color filter, or a MEMS device) using the above-described planarization apparatus will be described. This manufacturing method includes planarizing a composition placed on a substrate (such as a wafer or a glass substrate) using a film forming apparatus as the planarization apparatus and curing the composition. As a result, a planarization film is formed on the substrate. Then, a process of forming a pattern on the substrate on which the planarization film is formed is performed using a lithography apparatus, and the processed substrate undergoes other well-known processing steps, whereby an article is manufactured. The other well-known steps include patterning exposure and its preceding steps, etching, resist stripping, dicing, bonding, and packaging. This manufacturing method is capable of manufacturing an article of higher quality than conventional methods.

That is, the following forms are provided.

### (Form 1)

A planarization apparatus configured to form a planarization layer on a substrate by bringing a planarization member into contact with a planarization material on the substrate, the planarization apparatus including a drive unit configured to move the planarization member and the substrate relative to each other, and a control unit configured to control the drive unit, wherein the control unit controls a position of the planarization member relative to the substrate based on information about a defect on the planarization member and information about a tolerance region of the substrate where a defect is tolerated.

### (Form 2)

The planarization apparatus according to Form 1, wherein the control unit controls the position of the planarization member relative to the substrate so that at least one defect on the planarization member is positioned opposite the tolerance region of the substrate.

### (Form 3)

The planarization apparatus according to Form 2, wherein the control unit controls the position of the planarization member relative to the substrate with respect to a θ-axis so that at least one defect on the planarization member is positioned opposite the tolerance region of the substrate.

### (Form 4)

The planarization apparatus according to Form 2 or 3, wherein the control unit controls the position of the planarization member relative to the substrate with respect to the θ-axis, an X-axis, and a Y-axis so that at least one defect on the planarization member is positioned opposite the tolerance region of the substrate.

### (Form 5)

The planarization apparatus according to any one of Forms 2 to 4, wherein the control unit controls the position of the planarization member relative to the substrate with respect to an X-axis and a Y-axis so that at least one defect on the planarization member is positioned opposite the tolerance region of the substrate.

### (Form 6)

The planarization apparatus according to any one of Forms 1 to 5, wherein the control unit controls the position of the planarization member relative to the substrate further based on information about a mark on the planarization member.

### (Form 7)

The planarization apparatus according to Form 6, wherein the planarization member includes a T7 mark of the Semiconductor Equipment and Materials International (SEMI) standard, and wherein the control unit refers to the T7 mark of the SEMI standard and controls the position of the planarization member relative to the substrate with respect to a θZ-axis.

### (Form 8)

The planarization apparatus according to Form 6 or 7, wherein the planarization member includes a notch, and wherein the control unit refers to the notch and controls the position of the planarization member relative to the substrate with respect to a θZ-axis.

### (Form 9)

The planarization apparatus according to any one of Forms 2 to 8, wherein the control unit controls the position of the planarization member relative to the substrate with respect to an X-axis and a Y-axis within a wafer edge exclusion (WEE) range of the substrate so that at least one defect on the planarization member is positioned opposite the tolerance region of the substrate.

### (Form 10)

The planarization apparatus according to any one of Forms 2 to 9, wherein the control unit controls the position of the planarization member relative to the substrate so that the defect with the largest area on the planarization member is positioned opposite the tolerance region of the substrate.

### (Form 11)

The planarization apparatus according to any one of Forms 1 to 10, wherein the information about the defect on the planarization member is information acquired based on information about a defect on the substrate planarized using the planarization member.

### (Form 12)

The planarization apparatus according to any one of Forms 1 to 11, wherein the information about the defect on the planarization member is information about the defect on the planarization member that is acquired using a defect inspection apparatus.

### (Form 13)

A planarization method for forming a planarization layer on a substrate by bringing a planarization member into contact with a planarization material on the substrate, the planarization method including adjusting a position of the planarization member relative to the substrate based on information about a defect on the planarization member and information about a tolerance region of the substrate where a defect is tolerated so that at least one defect on the planarization member is positioned opposite the tolerance region of the substrate.

### (Form 14)

An article manufacturing method including forming a planarization layer on a substrate using the planarization method according to Form 13, and processing the substrate on which the planarization layer has been formed, wherein an article is manufactured from the processed substrate.

### (Form 15)

An article manufacturing method including forming a planarization layer on a substrate using the planarization apparatus according to any one of Forms 1 to 11, and processing the substrate on which the planarization layer has been formed, wherein an article is manufactured from the processed substrate.

While various preferred exemplary embodiments of the present disclosure have been described above, the exemplary embodiments of the present disclosure are described only as examples and are not intended to limit the scope of the present disclosure. The possible exemplary embodiments can be implemented in various forms. Within the scope of the essence of the present disclosure, changes in size, changes in position, omission of content, substitution, or changes in shape can be made. These changes are included within the scope and essence of the present disclosure.

As described above, the planarization apparatus capable of reducing the occurrences of defective chips caused by defects on the planarization member is provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-078778, filed May 14, 2024, which is hereby incorporated by reference herein in its entirety.

What is claimed is:

1. A planarization apparatus configured to form a planarization layer on a substrate by bringing a planarization member into contact with a planarization material on the substrate, the planarization apparatus comprising:
a drive unit configured to move the planarization member and the substrate relative to each other; and
a control unit configured to control the drive unit,
wherein the control unit controls a position of the planarization member relative to the substrate based on information about a defect on the planarization member and information about a tolerance region of the substrate where a defect is tolerated.

2. The planarization apparatus according to claim 1, wherein the control unit controls the position of the planarization member relative to the substrate so that at least one defect on the planarization member is positioned opposite the tolerance region of the substrate.

3. The planarization apparatus according to claim 2, wherein the control unit controls the position of the planarization member relative to the substrate with respect to a θ-axis so that at least one defect on the planarization member is positioned opposite the tolerance region of the substrate.

4. The planarization apparatus according to claim 2, wherein the control unit controls the position of the planarization member relative to the substrate with respect to a θ-axis, an X-axis, and a Y-axis so that at least one defect on the planarization member is positioned opposite the tolerance region of the substrate.

5. The planarization apparatus according to claim 2, wherein the control unit controls the position of the planarization member relative to the substrate with respect to an X-axis and a Y-axis so that at least one defect on the planarization member is positioned opposite the tolerance region of the substrate.

6. The planarization apparatus according to claim 1, wherein the control unit controls the position of the planarization member relative to the substrate further based on information about a mark on the planarization member.

7. The planarization apparatus according to claim 6,
wherein the planarization member includes a T7 mark of the Semiconductor Equipment and Materials International (SEMI) standard, and
wherein the control unit refers to the T7 mark of the SEMI standard and controls the position of the planarization member relative to the substrate with respect to a θZ-axis.

8. The planarization apparatus according to claim 6,
wherein the planarization member includes a notch, and
wherein the control unit refers to the notch and controls the position of the planarization member relative to the substrate with respect to a θZ-axis.

9. The planarization apparatus according to claim 2, wherein the control unit controls the position of the planarization member relative to the substrate with respect to an X-axis and a Y-axis within a wafer edge exclusion (WEE) range of the substrate so that at least one defect on the planarization member is positioned opposite the tolerance region of the substrate.

10. The planarization apparatus according to claim 2, wherein the control unit controls the position of the planarization member relative to the substrate so that the defect with the largest area on the planarization member is positioned opposite the tolerance region of the substrate.

11. The planarization apparatus according to claim 1, wherein the information about the defect on the planarization member is information acquired based on information about a defect on the substrate planarized using the planarization member.

12. The planarization apparatus according to claim 1, wherein the information about the defect on the planarization member is information about the defect on the planarization member that is acquired using a defect inspection apparatus.

13. A planarization method for forming a planarization layer on a substrate by bringing a planarization member into contact with a planarization material on the substrate, the planarization method comprising:
adjusting a position of the planarization member relative to the substrate based on information about a defect on the planarization member and information about a tolerance region of the substrate where a defect is tolerated so that at least one defect on the planarization member is positioned opposite the tolerance region of the substrate.

14. An article manufacturing method comprising:
forming a planarization layer on a substrate using a planarization method for forming a planarization layer on a substrate by bringing a planarization member into contact with a planarization material on the substrate, adjusting a position of the planarization member relative to the substrate based on information about a defect on the planarization member and information about a tolerance region of the substrate where a defect is tolerated so that at least one defect on the planarization member is positioned opposite the tolerance region of the substrate; and
processing the substrate on which the planarization layer has been formed,
wherein an article is manufactured from the processed substrate.

15. An article manufacturing method comprising:
forming a planarization layer on a substrate using the planarization apparatus according to claim 1; and
processing the substrate on which the planarization layer has been formed,
wherein an article is manufactured from the processed substrate.
